(19) United States
(12) Patent Application Publication
(10) Pub. No.: US 2012/0195109 A1
(43) Pub. Date: Aug. 2, 2012

(54) SEMICONDUCTOR STORAGE DEVICE

(75) Inventor: Hiromi Noro, Kanagawa (JP)

(73) Assignee: KABUSHIKI KAISHA TOSHIBA, Tokyo (JP)

(21) Appl. No.: 13/237,251

(22) Filed: Sep. 20, 2011

(30) Foreign Application Priority Data
Jan. 28, 2011 (JP) 2011-016987

(51) Int. Cl. G11C 11/412; G11C 7/08

(52) U.S. Cl. 365/154; 365/189.15

(57) ABSTRACT

According to one embodiment, a sense amplifier detects data stored in a memory cell based on potentials of bit lines of a bit line pair where bit line pairs are provided to correspond to columns of a memory cell array, respectively. Dummy cells are provided to correspond to rows of the memory cell array, respectively to simulate a read operation of the memory cells. A dummy bit line pair is driven in a complementary manner based on data read from the dummy cell. A read control unit controls the read operation of the memory cells based on the potential difference between dummy bit lines of the dummy bit line pair.

### CROSS-REFERENCE TO RELATED APPLICATIONS

This application is based upon and claims the benefit of priority from Japanese Patent Application No. 2011-16987, filed on Jan. 28, 2011; the entire contents of which are incorporated herein by reference.

### FIELD

Embodiments described herein relate generally to a semiconductor storage device.

### BACKGROUND

In a read operation of a static random access memory (SRAM), bit lines of all columns are precharged to a high level and then a word line of a selected row is turned on, so that the potential of a bit line of a selected column is controlled according to data held in a selected cell. At this time, since a non-selected cell sharing a word line together with the selected cell is likely to be activated, charge of a bit line of the non-selected cell may be discharged through the non-selected cell, resulting in an increase of power consumption.

### BRIEF DESCRIPTION OF THE DRAWINGS

FIG. 1 is a block diagram illustrating the schematic configuration of a semiconductor storage device according to an embodiment;

FIG. 2 is a timing chart illustrating an example of a voltage waveform of each element of the semiconductor storage device of FIG. 1;

FIG. 3 is a circuit diagram illustrating an example of the configuration of the memory cell of FIG. 1;

FIG. 4 is a circuit diagram illustrating an example of the configuration of the dummy cell of FIG. 1;

FIG. 5 is a circuit diagram illustrating an example of the configuration of the precharge & equalizer circuit corresponding to one column of FIG. 1;

FIG. 6 is a circuit diagram illustrating an example of the configuration of the sense amplifier and the output buffer of FIG. 1;

FIG. 7 is a block diagram illustrating an example of the configuration of the dummy bit line potential difference comparator, the sense amplifier controller, and the precharge controller of FIG. 1; and

FIG. 8 is a diagram illustrating the relation between the potential difference ΔVbl between bit lines, by which the sense amplifier of FIG. 1 is activated, and a power supply voltage VDD.

### DETAILED DESCRIPTION

A semiconductor storage device according to an embodiment includes a memory cell array, bit line pairs, word lines, a sense amplifier, dummy cells, dummy bit line pairs, and a read controller. In the memory cell array, memory cells for storing data in a complementary manner are arranged in a matrix form in the row direction and the column direction. The bit line pair are provided for each column of the memory cell array and are driven in a complementary manner based on data read from the memory cells. The word lines are provided to correspond to rows of the memory cell array, respectively to select corresponding row of the memory cell array. The sense amplifier detects the data stored in the memory cell based on the potentials of bit lines of the bit line pair. The dummy cells are provided to correspond to rows of the memory cell array, respectively to simulate the read operation of the memory cells. The dummy bit line pair is driven in a complementary manner based on data read from the memory cell. The read controller controls the read operation of the memory cells based on the potential difference between dummy bit lines of the dummy bit line pair.

Hereinafter, the semiconductor storage device according to the embodiment will be described with reference to the accompanying drawings. In addition, the present invention is not limited to the embodiment.

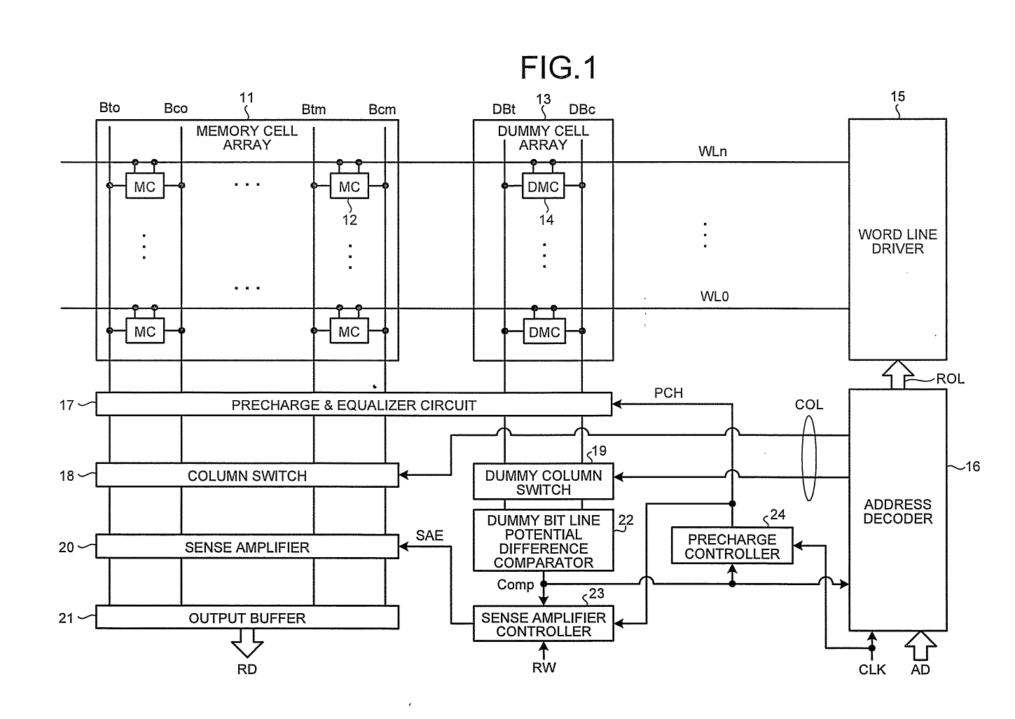

FIG. 1 is a block diagram illustrating the schematic configuration of the semiconductor storage device according to the embodiment.

In FIG. 1, the semiconductor storage device includes a memory cell array 11, a dummy cell array 13, a word line driver 15, an address decoder 16, a precharge & equalizer circuit 17, a column switch 18, a dummy column switch 19, a sense amplifier 20, an output buffer 21, a dummy bit line potential difference comparator 22, a sense amplifier controller 23, and a precharge controller 24.

In the memory cell array 11, memory cells 12 for storing data in a complementary manner are arranged in a matrix form in the row direction and the column direction. Furthermore, in the memory cell array 11, word lines WL0 to WLn for selecting rows of the memory cells 12 are provided to correspond to rows, respectively, and bit line pairs Bt0 to Btm and Bc0 to Bcm for selecting columns of the memory cells 12 are provided to correspond to columns, respectively. In addition, the bit line pairs Bt0 to Btm and Bc0 to Bcm are driven in a complementary manner based on data read from the memory cells 12.

In the dummy cell array 13, each of dummy cells 14 for simulating the read operation of the memory cells 12 is arranged for one row. In addition, the dummy cells 14 can store fixed data in a complementary manner.

Furthermore, in the dummy cells 14, the word lines WL0 to WLn are shared by the memory cells 12 for each row. Thus, data from the dummy cells 14 can be read at the same timing as data from the memory cells 12. Furthermore, the dummy cell array 13 is provided with dummy bit line pairs DBt and DBc driven in a complementary manner based on data read from the dummy cells 14.

Before data is read from the memory cells 12, the precharge & equalizer circuit 17 can precharge the bit line pairs Bt0 to Btm and Bc0 to Bcm to a high level and equalize the bit line pairs Bt0 to Btm and Bc0 to Bcm.

The column switch 18 can select any of the bit line pairs Bt0 to Btm and Bc0 to Bcm which allow columns of the memory cell array 11 to be selected. The dummy column switch 19 can select the dummy bit line pair DBt and DBc of the dummy cell array 13.

The sense amplifier 20 can detect data stored in the memory cells 12 based on signals that are read from the memory cells 12 and output to the bit line pairs Bt0 to Btm and Bc0 to Bcm in a complementary manner. The output buffer 21 can output read data RD based on detection results by the sense amplifier 20.

In addition, when the potential difference between dummy bit lines DBt and DBc of the dummy bit line pair is equal to or less than a threshold value TH, the dummy bit line potential difference comparator 22 can set comparison result Comp to a high level. When the potential difference between the dummy bit lines DBt and DBc of the dummy bit line pair exceeds the threshold value TH, the dummy bit line potential difference comparator 22 can set the comparison result Comp to a low level. Furthermore, the threshold value TH can be determined from mismatch tolerance of the sense amplifier 20, and for example, can be set in the range of about 100 mV to about 150 mV.

The precharge controller 24 can control the precharge timing of the bit line pairs Bt0 to Btm and Bc0 to Bcm based on the comparison result Comp of the potential difference between the dummy bit lines DBt and DBc of the dummy bit line pair.

The address decoder 16 can control the driving timing of the word lines WL0 to WLn of selected rows based on the comparison result Comp of the potential difference between the dummy bit lines DBt and DBc of the dummy bit line pair. The word line driver 15 can drive the word lines WL0 to WLn of selected rows designated by the address decoder 16.

In the semiconductor storage device, when a potential difference which is sufficiently large so as to detecting data stored in the memory cells 12 using the comparison result Comp occurs in the bit line pairs Bt0 to Btm and Bc0 to Bcm of selected columns, the sense amplifier 20 can be activated, and the row selection performed by the word lines WL0 to WLn can be released. Consequently, it is possible to reduce power consumption while reducing timing mismatch.

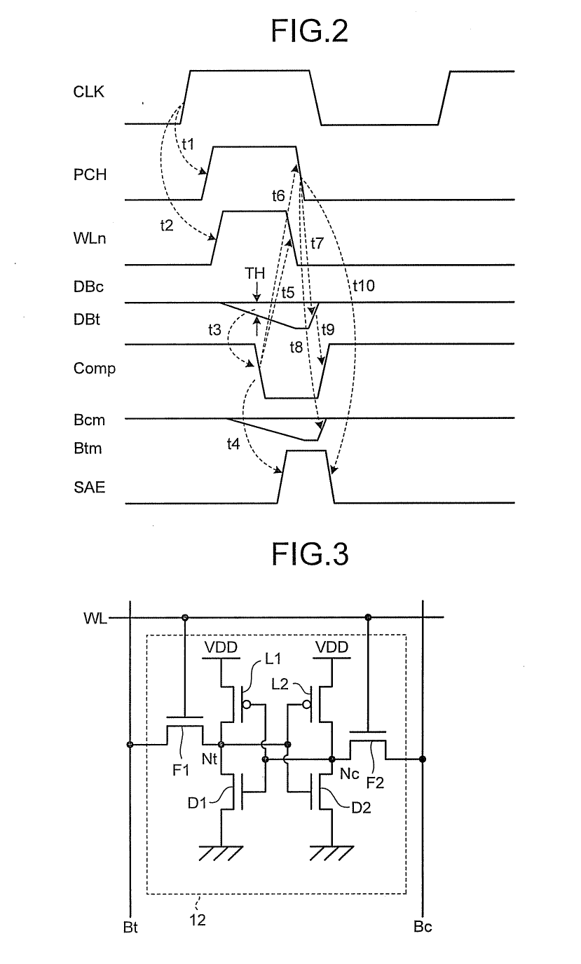

FIG. 2 is a timing chart illustrating an example of a voltage waveform of each element of the semiconductor storage device of FIG. 1.

In FIG. 2, if an address AD is input to the address decoder 16, a column select signal COL is generated based on the address AD and is output to the column switch 18 and the dummy column switch 19. Then, the column switch 18 selects a column designated by the column select signal COL and the bit lines pair Btm and Bcm of the selected column is connected to the sense amplifier 20. Furthermore, if the column select signal COL is input to the dummy column switch 19, the dummy column switch 19 is turned on and the dummy bit line pair DBt and DBc is connected to the dummy bit line potential difference comparator 22.

Then, in the dummy bit line potential difference comparator 22, the potentials of the dummy bit lines DBt and DBc of the dummy bit line pair are compared and hence the potential difference between the dummy bit lines of the dummy bit line pair DBt and DBc is generated as the comparison result Comp and is outputted to the address decoder 16, the sense amplifier controller 23, and the precharge controller 24.

If the comparison result Comp of the potential difference between the dummy bit lines DBt and DBc of the dummy bit line pair is input to the precharge controller 24, the precharge controller 24 generates a precharge signal PCH based on the comparison result Comp of the potential difference and outputs the precharge signal PCH to the precharge & equalizer circuit 17.

Furthermore, the comparison result Comp of the potential difference between the dummy bit lines DBt and DBc of the dummy bit line pair is input to the sense amplifier controller 23, the sense amplifier controller 23 generates a sense amplifier enable signal SAE based on the comparison result Comp of the potential difference and outputs the sense amplifier enable signal SAE to the sense amplifier 20.

Here, before the precharge signal PCH rises, the precharge & equalizer circuit 17 are activated, and the bit line pairs Bt0 to Btm and Bc0 to Bcm and the dummy bit line pair DBt and DBc are precharged to a high level. Therefore, the potential difference between the dummy bit lines DBt and DBc of the dummy bit line pair is equal to or less than the threshold value TH, and the sense amplifier enable signal SAE is set to a low level by the sense amplifier controller 23. As a consequence, the sense amplifier 20 is deactivated, so that the operation of the sense amplifier 20 is stopped.

Then, when the potential difference between the dummy bit lines DBt and DBc of the dummy bit line pair is equal to or less than the threshold value TH, the precharge controller 24 allows the precharge signal PCH to rise (t1) in response to the rising of a clock signal CLK. If the precharge signal PCH rises, the precharge & equalizer circuit 17 is deactivated, so that the bit lines in each of the bit line pairs Bt0 to Btm and Bc0 to Bcm are isolated from each other and the dummy bit lines DBt and DBc of the dummy bit line pair are isolated from each other.

Furthermore, when the potential difference between the dummy bit lines DBt and DBc of the dummy bit line pair is equal to or less than the threshold value TH, if the clock signal CLK rises, the address decoder 16 generates a row select signal ROL based on the address AD and outputs the row select signal ROL to the word line driver 15. Then, a row designated by the row select signal ROL is selected by the word line driver 15 and the potential of the word line WLn of the selected row rises (t2).

If the potential of the word line WLn of the selected row rises, data is read from the memory cell 12 and the dummy cell 14 which share the word line WLn with the memory cell 12. Therefore, a potential difference occurs in each of the bit line pairs Bt0 to Btm and Bc0 to Bcm based on the data read from the memory cells 12, and the potential difference between the bit lines Btm and Bcm of the bit line pair of the selected column is input to the sense amplifier 20 through the column switch 18.

Furthermore, a potential difference occurs in the dummy bit line pair DBt and DBc based on the data read from the selected dummy cell 14, and the potential difference between the dummy bit lines DBt and DBc of the dummy bit line pair is input to the dummy bit line potential difference comparator 22 through the dummy column switch 19.

Here, since the potential difference between the dummy bit lines of DBt and DBc the dummy bit line pair is allowed to accurately follow the potential difference between the bit lines of the bit line pair Btm and Bcm, it is preferable that the dummy cell 14 has the same size as the memory cell 12. That is, it is preferable that the dummy cell 14 includes a transistor having the same size as a transistor of the memory cell 12.

Then, if the potential difference between the dummy bit lines DBt and DBc of the dummy bit line pair exceeds the threshold value TH, the dummy bit line potential difference comparator 22 allows the comparison result Comp to fall (t3). Then, if the comparison result Comp fall, the sense amplifier controller 23 allows the sense amplifier enable signal SAE to rise (t4), so that the sense amplifier 20 is activated. Therefore, the sense amplifier 20 detects data stored in a selected cell based on the potential difference between the bit lines of the bit line pair Btm and Bcm of the selected column, and outputs read data RD through the output buffer 21.

Here, when the potential difference between the dummy bit lines DBt and DBc of the dummy bit line pair reaches the threshold value TH, timing control starts to allow the sense amplifier enable signal SAE to rise, so that it is possible to quickly activate the sense amplifier 20 when a potential difference sufficient for detecting the data stored in the memory cell 12 occurs in the bit line pair Btm and Bcm, resulting in a considerable increase in a data read speed.

Furthermore, if the comparison result Comp falls, the address decoder 16 gives an instruction to the word line driver 15 such that the potential of the word line WLn of the selected row falls. Then, the word line driver 15 allows the potential of the word line WLn of the selected row to fall (t5) according to the instruction from the address decoder 16.

Furthermore, if the comparison result Comp falls, the precharge controller 24 allows the precharge signal PCH to fall (t6). Then, if the precharge signal PCH falls, the precharge & equalizer circuit 17 is activated, so that the bit line pairs Bt0 to Btm and Bc0 to Bcm and the dummy bit line pair DBt and DBc are precharged to a high level (t7 and t8).

Here, the potential of the word line WLn and the precharge signal PCH falls, thereby preventing the bit line pairs Bt0 to Btm and Bc0 to Bcm from being discharged through the memory cells 12. Then, when the potential difference between the dummy bit lines DBt and DBc the dummy bit line pair reaches the threshold value TH, timing control is started to allow the potential of the word line WLn and the precharge signal PCH to fall, thereby preventing the bit line pairs Bt0 to Btm and Bc0 to Bcm from being quickly discharged after the sense amplifier 20 is activated. Consequently, it is possible to reduce the discharge time of the bit line pairs Bt0 to Btm and Bc0 to Bcm while ensuring the minimum time required for detecting data stored in the selected cell using the sense amplifier 20, resulting in a reduction of power consumption.

Furthermore, the precharge signal PCH falls, so that the sense amplifier enable signal SAE falls (t10) and the sense amplifier 20 is deactivated. Then, if the potential difference between the dummy bit lines DBt and DBc of the dummy bit line pair is equal to or less than the threshold value TH, the comparison result Comp rises (t9).

In addition, if the power supply voltage of the memory cell 12 changes, the driving power of the memory cell 12 changes. For example, if the power supply voltage becomes high, the driving power of the memory cell 12 becomes high and a cell current increases. Accordingly, the occurrence of the potential difference between the bit lines Btm and Bcm of the bit line pair is advanced. Meanwhile, if the power supply voltage becomes high, the driving power of the dummy cell 14 also becomes high and a dummy current increases. Accordingly, the occurrence of the potential difference between the dummy bit lines DBt and DBc of the dummy bit line pair is also advanced. Thus, since the falling of the comparison result Comp is also advanced, even when the occurrence of the potential difference between the bit lines DBt and DBc of the bit line pair is advanced, the activation timing of the sense amplifier 20 can be advanced, so that it is possible to control the read timing according to power dependence of the driving power of the memory cell 12.

Furthermore, dummy cells 14 are provided to correspond to the rows, respectively, so that the memory cell 12 and the dummy cell 14 of the selected row can be driven with the same word line among the word lines WL0 to WLn. Thus, even when a variation occurs in the rising timing of the potentials of the word lines WL0 to WLn between rows, it is possible to suppress the occurrence of a variation in the timing at which the potential difference occurs between the bit lines Bt0 to Btm and Bc0 to Bcm of the bit line pairs and the dummy bit lines DBt and DBc of the dummy bit line pair.

FIG. 3 is a circuit diagram illustrating an example of the configuration of the memory cell 12 of FIG. 1.

In FIG. 3, the memory cell 12 includes a pair of driving transistors D1 and D2, a pair of load transistors L1 and L2, and a pair of transmission transistors F1 and F2. In addition, p channel field-effect transistors can be used as the load transistors L1 and L2, and N channel field-effect transistors can be used as the driving transistors D1 and D2 and the transmission transistors F1 and F2.

Here, the driving transistor D1 and the load transistor L1 are connected in series to each other to form a CMOS inverter, and a storage node Nt is provided at the connection point between the driving transistor D1 and the load transistor L1. The driving transistor D2 and the load transistor L2 are connected in series to each other to form a CMOS inverter, and a storage node Nc is provided at the connection point between the driving transistor D2 and the load transistor L2. Furthermore, the output and the input of a pair of the CMOS inverters are cross-coupled to each other to form a flip-flop.

The word line WL is connected to the gates of the transmission transistors F1 and F2. Furthermore, the bit line Bt is connected to the storage node Nt through the transmission transistor F1. Furthermore, the bit line Bc is connected to the storage node Nc through the transmission transistor F2. In addition, the word line WL corresponds to any one of the word lines WL0 to WLn of FIG. 1, the bit line Bt corresponds to any one of the bit lines Bt0 to Btm of FIG. 1, and the bit line Bc corresponds to any one of the bit lines Bc0 to Bcm of FIG. 1.

Data is stored in the storage nodes Nt and Nc in a complementary manner. That is, when a logic value ‘1’ is stored in the storage node Nt, a logic value ‘0’ is stored in the storage node Nc. When a logic value ‘0’ is stored in the storage node Nt, a logic value ‘1’ is stored in the storage node Nc.

As illustrated in FIG. 2, if the potential of the word line WL rises, the transmission transistors F1 and F2 are turned on. Thus, the bit lines Bt and Bc of the bit line pair are driven in a complementary manner according to the data held in the storage nodes Nt and Nc, so that a potential difference occurs between the bit lines DBt and DBc of the bit line pair. Then, the potential difference having occurred between the bit lines DBt and DBc of the bit line pair is input to the sense amplifier 20 through the column switch 18 of FIG. 1.

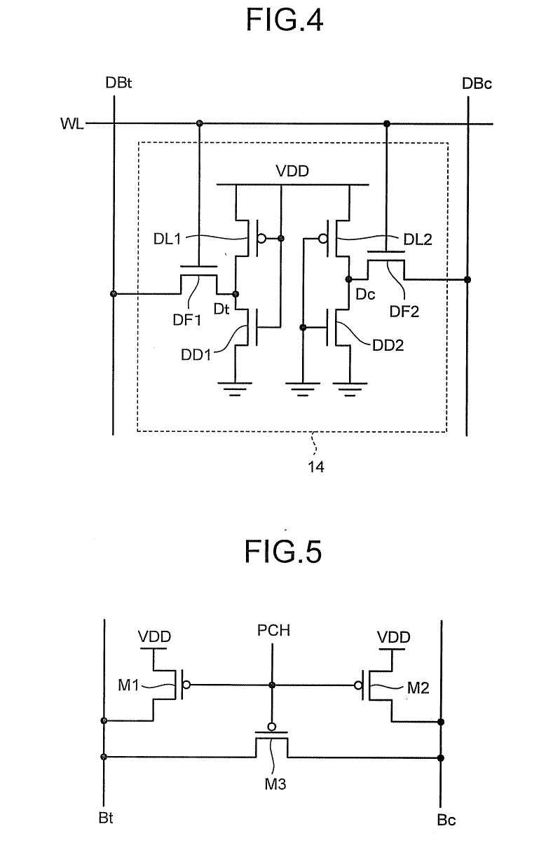

FIG. 4 is a circuit diagram illustrating an example of the configuration of the dummy cell 14 of FIG. 1

In FIG. 4, the dummy cell 14 includes a pair of dummy driving transistors DD1 and DD2, a pair of dummy load transistors DL1 and DL2, and a pair of dummy transmission transistors DF1 and DF2. In addition, p channel field-effect transistors can be used as the dummy load transistors DL1 and DL2, and N channel field-effect transistors can be used as the dummy driving transistors DD1 and DD2 and the dummy transmission transistors DF1 and DF2.

Furthermore, the dummy driving transistors DD1 and DD2 can be set to have the same size and threshold voltage as the driving transistors D1 and D2. The dummy load transistors DL1 and DL2 can be set to have the same size and threshold voltage as the load transistors L1 and L2. The dummy transmission transistors DF1 and DF2 can be set to have the same size and threshold voltage as the transmission transistors F1 and F2.

Here, the dummy driving transistor DD1 and the dummy load transistor DL1 are connected in series to each other to form a dummy CMOS inverter, and a dummy node Dt is provided at the connection point between the dummy driving transistor DD1 and the dummy load transistor DL1. The dummy driving transistor DD2 and the dummy load transistor DL2 are connected in series to each other to form a dummy CMOS inverter, and a dummy node Dc is provided at the connection point between the dummy driving transistor DD2 and the dummy load transistor DL2.

The input of the dummy CMOS inverter including the dummy driving transistor DD1 and the dummy load transistor DL1 is connected to a power supply potential VDD, so that a logic value ‘0’ is fixedly stored in the dummy node Dt. Furthermore, the input of the dummy CMOS inverter including the dummy driving transistor DD2 and the dummy load transistor DL2 is connected to a ground potential, so that a logic value ‘1’ is fixedly stored in the dummy node Dc.

The word line WL is connected to the gates of the dummy transmission transistors DF1 and DF2. Furthermore, the dummy bit line DBt is connected to the dummy node Dt through the dummy transmission transistor DF1. Furthermore, the dummy bit line DBc is connected to the dummy node Dc through the dummy transmission transistor DF2.

As illustrated in FIG. 2, if the potential of the word line WL rises, the dummy transmission transistors DF1 and DF2 are turned on. Thus, the dummy bit lines DBt and DBc of the dummy bit line pair are driven in a complementary manner according to the data held in the dummy nodes Dt and Dc, so that a potential difference occurs between the dummy bit lines DBt and DBc of the dummy bit line pair. Then, the potential difference having occurred between the dummy bit lines DBt and DBc of the dummy bit line pair is input to the dummy bit line potential difference comparator 22 through the dummy column switch 19 of FIG. 1.

FIG. 5 is a circuit diagram illustrating an example of the configuration of the precharge & equalizer circuit 17 corresponding to one column of FIG. 1.

In FIG. 5, the precharge & equalizer circuit 17 includes precharge transistors M1 to M3. In addition, P channel field-effect transistors can be used as the precharge transistors M1 to M3. The gates of the precharge transistors M1 to M3 are connected to one another to receive the precharge signal PCH. Furthermore, the precharge transistor M3 is connected between the bit lines Bt and Bc. Furthermore, the bit line Bt is connected to the power supply potential VDD through the precharge transistor Ml, and the bit line Bc is connected to the power supply potential VDD through the precharge transistor M2.

Before data is read from the memory cells 12 of FIG. 1, the precharge signal PCH is maintained at a low level. Thus, the precharge transistors M1 to M3 are turned on and the bit line pair Bt and Bc and the dummy bit line pair DBt and DBc are connected to the power supply potential VDD, so that the bit line pair Bt and Bc and the dummy bit line pair DBt and DBc are precharged to a high level.

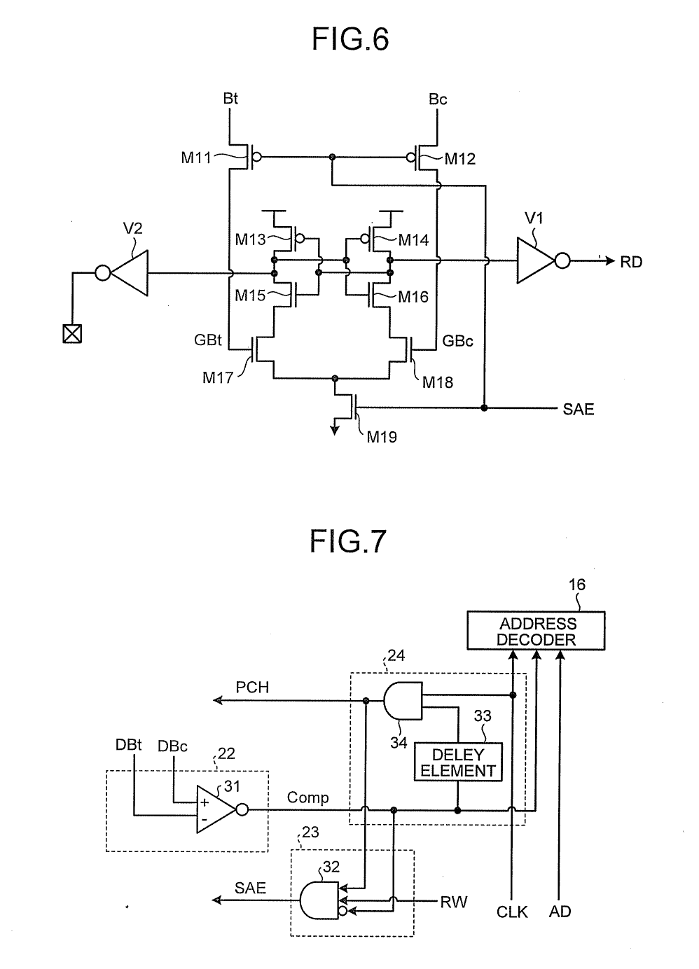

FIG. 6 is a circuit diagram illustrating an example of the configuration of the sense amplifier 20 and the output buffer 21 of FIG. 1.

In FIG. 6, the sense amplifier 20 includes isolation transistors M11 and M12, P channel field-effect transistors M13 and M14, and N channel field-effect transistors M15 to M19. In addition, P channel field-effect transistors can be used as the isolation transistors M11 and M12. The output buffer 21 includes inverters V1 and V2.

The P channel field-effect transistor M13 is connected in series to the N channel field-effect transistor M15, and the gate of the P channel field-effect transistor M13 and the gate of the N channel field-effect transistor M15 are connected to each other to form an inverter. Furthermore, the P channel field-effect transistor M14 is connected in series to the N channel field-effect transistor M16, and the gate of the P channel field-effect transistor M14 and the gate of the N channel field-effect transistor M16 are connected to each other to form an inverter. Furthermore, the output of one of a pair of the inverters is connected to the input of the other inverter to form a flip-flop.

Furthermore, the gate of the P channel field-effect transistor M13, the gate of the N channel field-effect transistor M15, the drain of the P channel field-effect transistor M14, and the drain of the N channel field-effect transistor M16 are connected to the input of an inverter V1. The gate of the P channel field-effect transistor M14, the gate of the N channel field-effect transistor M16, the drain of the P channel field-effect transistor M13, the drain of the N channel field-effect transistor M15 are connected to the input of an inverter V2.

Furthermore, the N channel field-effect transistor M17 is connected in series to the N channel field-effect transistor M15, and the N channel field-effect transistor M18 is connected in series to the N channel field-effect transistor M16. The sources of the N channel field-effect transistors M17 and M18 are connected to the drain of the N channel field-effect transistor M19.

Furthermore, the bit line Bt is connected to a global bit line GBt through the isolation transistor M11, and the bit line Bc is connected to a global bit line GBc through the isolation transistor M12. The global bit line GBt is connected to the gate of the N channel field-effect transistor M17, and the global bit line GBc is connected to the gate of the N channel field-effect transistor M18.

The sense amplifier enable signal SAE is input to the gates of the isolation transistors M11 and M12 and the gate of the N channel field-effect transistor M19.

In addition, the sense amplifier of FIG. 6 is not always provided for each column, and one sense amplifier may be shared by a plurality of columns.

As illustrated in FIG. 2, before data is read from the memory cells 12, the sense amplifier enable signal SAE is maintained at a low level. Thus, the N channel field-effect transistor M19 is turned off, the operation of the sense amplifier 20 is stopped, the isolation transistors M11 and M12 are turned on, and both the global bit line pairs GBt and GBc and the bit line pairs Bt and Bc are pre charged.

As illustrated in FIG. 2, the potential of the word line WLn of the selected row rises in the state in which the sense amplifier enable signal SAE is in the low level state, so that a potential difference occurs between the global bit lines GBt and GBc of the global bit line pair with the occurrence of a potential difference between the bit lines Btm and Bcm of the bit line pair, and a potential difference occurs between the dummy bit lines DBt and DBc of the dummy bit line pair.

Then, if the potential difference between the dummy bit lines DBt and DBc of the dummy bit line pair exceeds the threshold value TH, the sense amplifier enable signal SAE rises. Thus, the isolation transistors M11 and M12 are turned off, so that the global bit line pair GBt and GBc is separated from the bit line pair Bt and Bc, the sense amplifier 20 is activated, and data read from the selected cell is detected.

Here, the sense amplifier enable signal SAE rises when the potential difference between the dummy bit lines DBt and DBc of the dummy bit line pair has exceeded the threshold value TH, so that it is possible to quickly activate the sense amplifier 20 when a potential difference which is sufficiently large so as to detect the data stored in the memory cells 12 occurs between the global bit lines GBt and GBc of the global bit line pair.

Furthermore, the isolation transistors M11 and M12 are turned off when the potential difference between the dummy bit lines DBt and DBc of the dummy bit line pair has exceeded the threshold value TH, so that it is possible to separate the global bit line pair GBt and GBc from the bit line pair Bt and Bc when the potential difference which is sufficiently large so as to detect the data stored in the memory cells 12 occurs between the global bit lines GBt and BGc of the global bit line pair. Thus, it is possible to reduce redundant discharge to the global bit line pair GBt and GBc, resulting in a reduction of power consumption.

FIG. 7 is a block diagram illustrating an example of the configuration (a read controller) of the dummy bit line potential difference comparator 22, the sense amplifier controller 23, and the precharge controller 24 of FIG. 1.

In FIG. 7, the dummy bit line potential difference comparator 22 includes a comparator 31. The sense amplifier controller 23 includes an AND circuit 32. The precharge controller 24 includes a delay element 33 and an AND circuit 34. In addition, a logic circuit such as an inverter or a buffer can be used as the delay element 33. The number of stages of the logic circuit is adjusted, so that it is possible to adjust a delay time.

The comparator 31 compares the potential of the dummy bit line DBt with the potential of the dummy bit line DBc to determine whether the potential difference between the dummy bit lines DBt and DBc of the dummy bit line pair exceeds the threshold value TH. Then, the comparison result is output as the comparison result Comp of the potential difference between the dummy bit lines DBt and DBc of the dummy bit line pair, and the comparison result Comp is input to the AND circuit 34 through the delay element 33, and the address decoder 16. Furthermore, an inversion signal of the comparison result Comp is input to the AND circuit 32. Furthermore, a clock signal CLK is input to the AND circuit 34, and the precharge signal PCH and a read/write signal RW are input to the AND circuit 32. In addition, the read/write signal RW can be set to a high level at the time of a read operation, and a low level at the time of a write operation.

As illustrated in FIG. 2, after the AND circuit 32 allows the precharge signal PCH to rise at the time of the read operation, the comparison result Comp fall, so that the sense amplifier enable signal SAE rises, resulting in the activation of the sense amplifier 20.

Furthermore, if the comparison result Comp fall, the address decoder 16 gives an instruction to the word line driver 15 such that the potential of the word line WLn of the selected row falls. Then, the word line driver 15 allows the potential of the word line WLn of the selected row to fall based on the instruction from the address decoder 16.

Furthermore, the AND circuit 34 allows the clock signal CLK to rise and then allows the comparison result Comp to fall, so that the precharge signal PCH falls, resulting in the activation of the precharge & equalizer circuit 17. In addition, the delay element 33 can adjust the delay time such that the falling timing of the precharge signal PCH is coincident with or subsequent to the falling timing of the potential of the word line WLn.

In this way, when the potential difference between the dummy bit lines DBt and DBc of the dummy bit line pair has reached the threshold value TH, the sense amplifier enable signal SAE can rise and timing control can be started to allow the potential of the word line WLn and the precharge signal PCH to fall. Consequently, when the potential difference which is sufficiently large so as to detect the data stored in the memory cells 12 occurs between the bit lines Btm and Bcm of the bit line pair of the selected column, the sense amplifier 20 can be activated and the row selection performed by the word line WLn can be released. As a consequence, it is possible to reduce the discharge time of the bit line pairs Bt0 to Btm and Bc0 to Bcm while ensuring the minimum time required for detecting data stored in the selected cell using the sense amplifier 20, resulting in a reduction of power consumption.

In addition, the rising timing of the sense amplifier enable signal SAE and the falling timing of the potential of the word line WLn may be coincident with each other. Furthermore, the time that elapses until the precharge signal PCH falls after the sense amplifier enable signal SAE rises may be the time that elapses until the output of the sense amplifier 20 is fixed after the sense amplifier enable signal SAE rises. For example, since the output of the sense amplifier 20 is determined by a logic circuit of one gate or of two gates, it is sufficient that the time corresponding to this configuration is ensured.

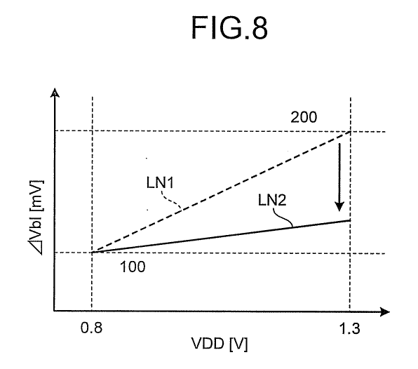

FIG. 8 is a diagram illustrating the relation between the potential difference ΔVbl between bit lines, by which the sense amplifier of FIG. 1 is activated, and the power supply voltage VDD.

In FIG. 8, in an SRAM macro (hereinafter, referred to as a wide range SRAM) in which a power supply voltage to be used has an amplitude, if the power supply voltage of the memory cell 12 changes, the driving power of the memory cell 12 changes. Thus, if the power supply voltage VDD becomes high, the occurrence of the potential difference ΔVbl between the bit lines Bt and Bc of the bit line pair is advanced.

For example, in the wide range SRAM, the rising timing of the sense amplifier enable signal SAE is set by a low voltage-side (the power supply voltage VDD=0.8 V) such that the potential difference ΔVbl between the bit lines Bt and Bc of the bit line pair is about 100 mV. In this case, since the driving power of the memory cell 12 increases at a high voltage-side (the power supply voltage VDD=1.3 V), the occurrence of the potential difference ΔVbl between the bit lines Bt and Bc of the bit line pair is advanced, so that the rising timing of the sense amplifier enable signal SAE is set (LN1) when the potential difference ΔVbl between the bit lines Bt and Bc of the bit line pair is about 200 mV.

If the potential difference ΔVbl between the bit lines Btm and Bcm of the bit line pair of the selected column increases when the sense amplifier enable signal SAE rises, since the potential difference ΔVbl between the bit lines Bt0 to Btm and Bc0 to Bcm of the bit line pairs of a non-selected column increases, the bit line pairs Bt0 to Btm and Bc0 to Bcm are increasingly discharged, resulting in an increase in power consumption.

Here, the sense amplifier enable signal SAE rises when the potential difference between the dummy bit lines DBt and DBc of the dummy bit line pair reaches the threshold value TH, so that it is possible to change the rising timing of the sense amplifier enable signal SAE according to an increase or a decrease in the power supply voltage VDD. Consequently, even in a case where the power supply voltage VDD is changed from the low voltage-side (the power supply voltage VDD=0.8 V) to high voltage-side (the power supply voltage VDD=1.3 V), it is possible to suppress an increase in the potential difference ΔVbl between the bit lines Bt and Bc of the bit line pair when the sense amplifier enable signal SAE rises (LN2), and to prevent the bit line pairs Bt0 to Btm and Bc0 to Bcm from being discharged, resulting in a reduction in power consumption.

In the description above, only one column of dummy cells 14 is provided. However, the dummy cells 14 may be provided in a plurality of columns. In that case, data of the dummy cells 14 may be simultaneously read from the plurality of columns, and the read operation of the memory cell 12 may be controlled based on a signal of a column in which the occurrence of the potential difference between dummy bit lines is most advanced. In this way, in the case in which one sense amplifier 20 is shared by a plurality of columns, even when the driving power of the memory cell 12 varies from column to column, it is possible to ensure a minimum time for detecting the data stored in the memory cell 12 using the sense amplifier 20.

Furthermore, in the above-mentioned embodiment, a method of arranging the dummy cell array 13 on a right end of the memory cell array 11 has been described. However, the dummy cell array 13 may also be arranged on a left end of the memory cell array 11. In this way, the dummy cell array 13 may be arranged far from the word line driver 15, as compared with the memory cell array 11. Consequently, even when signal propagation delay occurs in the word lines WL0 to WLn, it is possible to prevent the occurrence of the potential difference between the dummy bit lines DBt and DBc of the dummy bit line pair from being advanced as compared with the occurrence of the potential difference of each bit line pair of the bit line pairs Bt0 to Btm and Bc0 to Bcm, resulting in the prevention of an erroneous operation of the sense amplifier 20 and a reduction in power consumption. Moreover, the dummy cell array 13 may also be arranged in the memory cell array 11 as well as the ends of the memory cell array 11. For example, when the dummy cell array 13 is arranged in the middle portion of the memory cell array 11, the dummy cell array 13 can be controlled within an average delay time, so that power consumption can be further reduced while preventing an erroneous operation.

Furthermore, in the above-mentioned embodiment, a single bank structure has been described as an example. However, a multi-bank structure may also be employed. In this case, the dummy cell array 13 may be provided for each bank, and a read operation of a memory cell may be controlled for each bank based on the potential difference between the dummy bit lines DBt and DBc of the dummy bit line pair.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a memory cell array in which memory cells storing data in a complementary manner are arranged in a matrix form in a row direction and a column direction;
bit line pairs, each pair being provided to correspond to one column of the memory cell array and driven in a complementary manner based on data read from the memory cell;
word lines, each being provided to correspond to one row of the memory cell array to select a row of the memory cell array;
a sense amplifier that detects data stored in the memory cell based on potentials of bit lines of the bit line pair;
dummy cells, each being provided to correspond to one row of the memory cell array to simulate a read operation of the memory cell;
a dummy bit line pair driven in a complementary manner based on data read from the dummy cell; and
a read controller that controls the read operation of the memory cells based on a potential difference between dummy bit lines of the dummy bit line pair.

2. The semiconductor storage device according to claim 1,
wherein the read controller includes a sense amplifier controller that controls timing for activating the sense amplifier based on the potential difference between the dummy bit lines of the dummy bit line pair.

3. The semiconductor storage device according to claim 2,
wherein the sense amplifier controller includes a 3-input AND circuit,
a comparison result of the potential difference between the dummy bit lines of the dummy bit line pair is input to a first input terminal of the 3-input AND circuit,
a read/write signal is input to a second input terminal of the 3-input AND circuit, and
a precharge signal is input to a third input terminal of the 3-input AND circuit.

4. The semiconductor storage device according to claim 2,
wherein, when the potential difference between the dummy bit lines of the dummy bit line pair is equal to or less than a threshold value, the sense amplifier is deactivated.

5. The semiconductor storage device according to claim 4,
wherein, when the potential difference between the dummy bit lines of the dummy bit line pair exceeds the threshold value, the sense amplifier is activated.

6. The semiconductor storage device according to claim 1,
wherein the read controller includes a precharge controller that controls timing of precharge of the bit lines of the bit line pair based on the potential difference between the dummy bit lines of the dummy bit line pair.

7. The semiconductor storage device according to claim 6, further comprising a precharge and equalizer circuit that precharges the bit lines of the bit line pairs with a high level and equalize the bit lines of the bit line pairs before data is read from the memory cells.

8. The semiconductor storage device according to claim 7,
wherein the precharge controller includes:
a 2-input AND circuit;
a clock signal is input to a first input terminal of the 2-input AND circuit; and
a comparison result of the potential difference between the dummy bit lines of the dummy bit line pair is input to a second input terminal of the 2-input AND circuit through a delay element.

9. The semiconductor storage device according to claim 8,
wherein the delay element adjusts a delay time such that falling timing of a precharge signal is coincident with or subsequent to falling timing of a potential of the word line.

10. The semiconductor storage device according to claim 7,
wherein, when the potential difference between the dummy bit lines of the dummy bit line pair is equal to or less than a threshold value, the precharge and equalizer circuit is deactivated.

11. The semiconductor storage device according to claim 10,
wherein, when the potential difference between the dummy bit lines of the dummy bit line pair exceeds the threshold value, the precharge and equalizer circuit is activated.

12. The semiconductor storage device according to claim 1,
wherein the read controller includes an address decoder that controls driving timing of a word line of a selected row based on the potential difference between the dummy bit lines of the dummy bit line pair.

13. The semiconductor storage device according to claim 12, further comprising a word line driver that drives the word line of the selected row designated by the address decoder.

14. The semiconductor storage device according to claim 12,
wherein, when the potential difference between the dummy bit lines of the dummy bit line pair is equal to or less than a threshold value, the address decoder generates a row select signal based on an address and allows the word line of the selected row to drive.

15. The semiconductor storage device according to claim 14,
wherein, when the potential difference between the dummy bit lines of the dummy bit line pair exceeds the threshold value, the address decoder allows the word line of the selected row to release.

16. The semiconductor storage device according to claim 12, further comprising:
a column switch that selects a bit line pair selecting a column of the memory cell array;
a dummy column switch that selects the dummy bit line pair of the dummy cells; and
a dummy bit line potential difference comparator that compares potentials of the dummy bit lines of the dummy bit line pair to determine the potential difference of the dummy bit line pair.

17. The semiconductor storage device according to claim 16,
wherein the address decoder generates a column select signal based on an address, connects a bit line pair of a selected column to the sense amplifier through the column switch, and connects the dummy bit line pair to the dummy bit line potential difference comparator through the dummy column switch.

18. The semiconductor storage device according to claim 16,
wherein the dummy bit line potential difference comparator includes a comparator that determines whether the potential difference of the dummy bit line pair exceeds a threshold value.

19. The semiconductor storage device according to claim 1,
wherein the memory cell includes:
a first CMOS inverter in which a first driving transistor and a first load transistor are connected in series to each other, and a first storage node is provided at a connection point between the first driving transistor and the first load transistor;
a second CMOS inverter in which a second driving transistor and a second load transistor are connected in series to each other, and a second storage node is provided at a connection point between the second driving transistor and the second load transistor;
a first transmission transistor that is connected between the first storage node and one bit line of the bit line pair; and
a second transmission transistor that is connected between the second storage node and a remaining bit line of the bit line pair,
wherein outputs and inputs of the first CMOS inverter and the second CMOS inverter are cross-coupled to each other, and
a gate of the first transmission transistor and a gate of the second transmission transistor are connected to the word line,
wherein the dummy cell includes:
a first dummy CMOS inverter in which a first dummy driving transistor and a first dummy load transistor are connected in series to each other, and a first dummy node is provided at a connection point between the first dummy driving transistor and the first dummy load transistor;
a second dummy CMOS inverter in which a second dummy driving transistor and a second dummy load transistor are connected in series to each other, and a second dummy node is provided at a connection point between the second dummy driving transistor and the second dummy load transistor;
a first dummy transmission transistor that is connected between the first dummy node and one dummy bit line of the dummy bit line pair; and
a second dummy transmission transistor that is connected between the second dummy node and a remaining dummy bit line of the dummy bit line pair,
wherein an input of the first dummy CMOS inverter is connected to a power supply potential, an input of the second dummy CMOS inverter is connected to a ground potential, and
a gate of the first dummy transmission transistor and a gate of the second dummy transmission transistor are connected to the word line.

20. The semiconductor storage device according to claim 19,
wherein the first driving transistor and the first dummy driving transistor, the second driving transistor and the second dummy driving transistor, the first load transistor and the first dummy load transistor, the second load transistor and the second dummy load transistor, the first transmission transistor and the first dummy transmission transistor, and the second transmission transistor and the second dummy transmission transistor have the same size, respectively.
